(19) United States
(12) Patent Application Publication
(10) Pub. No.: US 2025/0210481 A1
(43) Pub. Date: Jun. 26, 2025

(54) SEMICONDUCTOR PACKAGE

(71) Applicant: SAMSUNG ELECTRONICS CO., LTD., SUWON-SI (KR)

(72) Inventor: Eunsu LEE, Suwon-si (KR)

(21) Appl. No.: 18/814,755

(22) Filed: Aug. 26, 2024

(30) Foreign Application Priority Data
Dec. 26, 2023 (KR) 10-2023-0191111

(51) Int. Cl. H01L 23/498; H01L 23/00; H01L 23/538; H01L 25/065; H01L 25/16; H10B 80/00

(52) U.S. Cl. CPC H01L 23/49816; H01L 23/5385; H01L 23/562; H01L 25/162; H01L 24/16; H01L 25/0657; H01L 2224/16227; H01L 2225/06513; H01L 2225/06517; H01L 2225/06541; H01L 2225/06565; H10B 80/00; H10D 1/68

(57) ABSTRACT

A semiconductor package includes a lower substrate comprising a lower interconnection layer. A first semiconductor chip is on the lower substrate and electrically connected to the lower interconnection layer. Connection structures are on the lower substrate and surround the first semiconductor chip. Support members are disposed on at least a portion of connection structures adjacent to side surfaces of the first semiconductor chip and edges of the lower substrate. An upper substrate is on the first semiconductor chip and the connection structures, and comprises an upper interconnection layer. A second semiconductor chip is on the upper substrate and is electrically connected to the upper interconnection layer. A third semiconductor chip is on the upper substrate and is electrically connected to the upper interconnection layer, spaced apart from the second semiconductor chip in a horizontal direction, and overlaps the first semiconductor chip in a vertical direction.

### CROSS-REFERENCE TO RELATED APPLICATION(S)

This application claims priority under 35 U.S.C. § 119 to Korean Patent Application No. 10-2023-0191111, filed on Dec. 26, 2023 in the Korean Intellectual Property Office, the disclosure of which is incorporated by reference in its entirety herein.

### 1. TECHNICAL FIELD

The present inventive concept relates to a semiconductor package, and more specifically, relates to a semiconductor package having increased integration and reliability.

### 2. DISCUSSION OF RELATED ART

Consumer demands for higher functionality, higher speed and miniaturization of electronic components are increasing along with the development of the electronics industry. Research is being conducted concerning a system in package (SIP), which requires complexity and multifunctionality in terms of functionality, to meet these consumer demands. A package on package (POP) structure is being developed in which multiple semiconductor chips are stacked and mounted on a package substrate or other semiconductor packages are stacked on a semiconductor package. Research is being actively conducted to simultaneously secure miniaturization and reliability in such semiconductor packages.

### SUMMARY

An object of an aspect of an embodiment of the present inventive concept is to provide a semiconductor package having increased integration and reliability.

However, the objects of embodiments of the present inventive concept are not limited to those mentioned herein, and can be variously extended without departing from the spirit and scope of the present inventive concept.

According to an embodiment of the present inventive concept, a semiconductor package includes a lower substrate comprising a lower interconnection layer. A first semiconductor chip is on the lower substrate and electrically connected to the lower interconnection layer. Connection structures are on the lower substrate and surround the first semiconductor chip. Support members are disposed on at least a portion of connection structures adjacent to side surfaces of the first semiconductor chip and edges of the lower substrate. An upper substrate is on the first semiconductor chip and the connection structures, and comprises an upper interconnection layer. A second semiconductor chip is on the upper substrate and is electrically connected to the upper interconnection layer. A third semiconductor chip is on the upper substrate and is electrically connected to the upper interconnection layer, spaced apart from the second semiconductor chip in a horizontal direction, and overlaps the first semiconductor chip in a vertical direction.

According to an embodiment of the present inventive concept, a semiconductor package includes a lower substrate comprising a first region and a second region spaced apart from the first region in a first direction. A first semiconductor chip is on the first region. The first semiconductor chip is electrically connected to the lower interconnection layer. Connection structures are on the first region and the second region. The connection structures surround the first semiconductor chip. Support members are disposed on at least a portion of connection structures adjacent to side surfaces of the first semiconductor chip and edges of the lower substrate of the connection structures. An upper substrate is disposed on the first semiconductor chip and the connection structures and overlaps therewith in a vertical direction. The upper substrate comprises an upper interconnection layer. A second semiconductor chip is on the upper substrate. The second semiconductor chip is electrically connected to the upper interconnection layer and overlaps the second region in the vertical direction. A third semiconductor chip is on the upper substrate. The third semiconductor chip is spaced apart from the second semiconductor chip in a horizontal direction and overlaps the first semiconductor chip in the vertical direction.

According to an embodiment of the present inventive concept, a semiconductor package includes a lower substrate comprising a first region and a second region spaced apart from the first region in a first direction. A capacitor is embedded in the lower substrate. A first semiconductor chip is on the first region. The first semiconductor chip is electrically connected to the lower interconnection layer. First connection structures are on the first region. The first connection structures are adjacent to side surfaces of the first semiconductor chip. Second connection structures are on the second region. The second connection structures are disposed at a same level as the first connection structures. Support members are disposed on at least a portion of the first connection structures and a portion of the second connection structures. An upper substrate is disposed on the first semiconductor chip, the first connection structures and the second connection structures and overlaps the lower substrate in a vertical direction. The upper substrate comprises an upper interconnection layer. A second semiconductor chip is on the upper substrate. The second semiconductor chip is electrically connected to the upper interconnection layer and overlaps the second region in the vertical direction. A third semiconductor chip is on the upper substrate. The third semiconductor chips is spaced apart from the second semiconductor chip in a horizontal direction and overlaps the first semiconductor chip in the vertical direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 illustrates a plan view of a semiconductor package according to an embodiment of the present inventive concept;

FIG. 2 is a cross-sectional view taken along line I-I′ in FIG. 1 according to an embodiment of the present inventive concept;

FIGS. 3A and 3B are plan views of the arrangement of the support members of the semiconductor package of FIG. 2 according to embodiments of the present inventive concept;

FIG. 4 is a cross-sectional view taken along line I-I′ in FIG. 1 according to an embodiment of the present inventive concept;

FIG. 5 is a plan view of the arrangement of the support members of the semiconductor package of FIG. 4 according to an embodiment of the present inventive concept;

FIG. 6 is a cross-sectional view taken along line I-I′ in FIG. 1 according to an embodiment of the present inventive concept;

FIG. 7 is a plan view of the arrangement of the support members of the semiconductor package of FIG. 6 according to an embodiment of the present inventive concept;

FIG. 8 is a cross-sectional view taken along line I-I′ in FIG. 1 according to an embodiment of the present inventive concept; and

FIGS. 9 to 14 are diagrams of a method of manufacturing the semiconductor package of FIG. 2 according to embodiments of the present inventive concept.

### DETAILED DESCRIPTION OF EMBODIMENTS

Hereinafter, non-limiting embodiments of the present inventive concept will be described with reference to the accompanying drawings. The same reference numerals are used for the same components in the drawings, and duplicate descriptions for the same components may be omitted for economy of description.

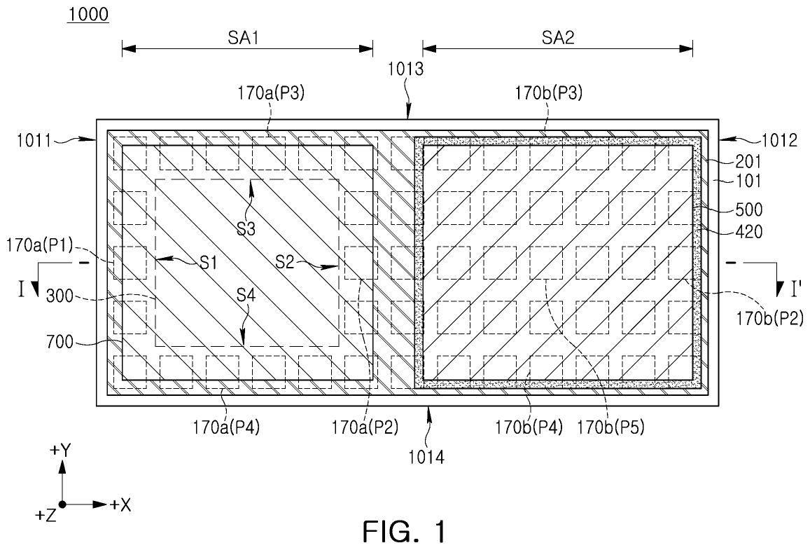

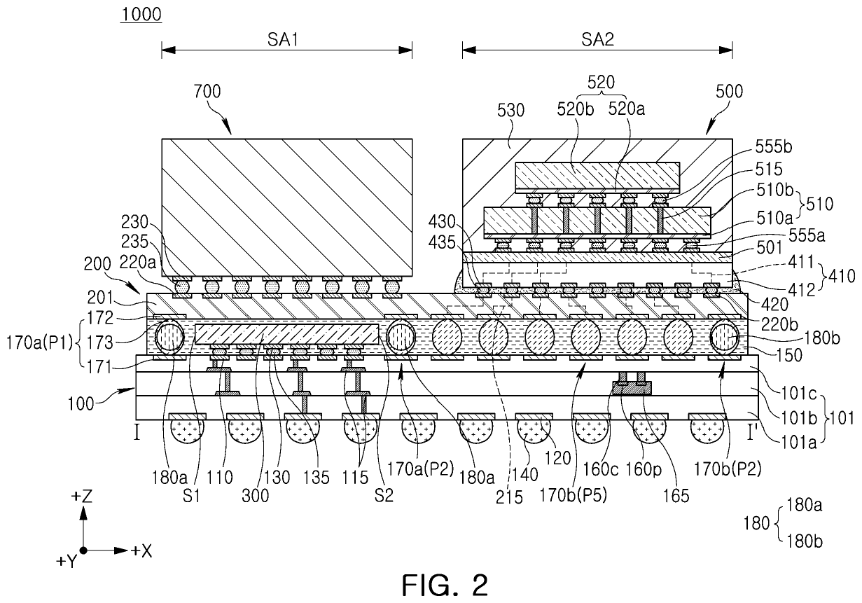

FIG. 1 illustrates a plan view of a semiconductor package according to an embodiment of the present inventive concept. FIG. 2 is a cross-sectional view taken along line I-I′ in FIG. 1 according to an embodiment of the present inventive concept.

Referring to FIGS. 1 and 2, in an embodiment a semiconductor package 1000 may include

a lower base 100, an upper base 200, a plurality of connection structures 170a and 170b, a first semiconductor chip 300, a second semiconductor chip 500, a third semiconductor chip 700 and a redistribution structure 410.

In an embodiment, the lower base 100 may include a lower substrate 101, a first upper pad 110, a first lower pad 120, a first interconnection circuit layer 115 electrically connecting the first upper pad 110 and the first lower pad 120, a lower connection bump 140, and a passive element 165.

In an embodiment, the lower substrate 101 is a support substrate on which the first semiconductor chip 300 is mounted, and may be a substrate for a semiconductor package including a printed circuit board (PCB), a ceramic substrate, a glass substrate, a tape interconnection substrate, and the like. In an embodiment, the lower substrate 101 may include different materials depending on the type of substrate. For example, in an embodiment in which the lower substrate 101 is a printed circuit board, the lower substrate 101 may be in a form in which an interconnection layer is additionally laminated on one or both sides of a copper clad laminate. In an embodiment, solder resist layers may be disposed on lower and upper surfaces of the lower substrate 101.

In an embodiment, the lower substrate 101 may include a first edge 1011 extending in a first direction (e.g., the +Y direction), a second edge 1012 extending in the first direction (e.g., the +Y direction) and spaced apart from the first edge 1011 in a second direction (e.g., the +X direction), a third edge 1013 extending in the second direction (e.g., the +X direction), and a fourth edge 1014 extending in the second direction (e.g., the +X direction) and spaced apart from the third edge 1013 in the first direction (e.g., the +Y direction). In an embodiment, the second edge 1012 may be substantially parallel to the first edge 1011 in the first direction (e.g., the +Y direction). The fourth edge 1014 may be substantially parallel to the third edge 1013 in the second direction (e.g., the +X direction). However, embodiments of the present inventive concept are not necessarily limited thereto.

In an embodiment, the lower substrate 101 may include a first region SA1 and a second region SA2 spaced apart from the first region SA1 in the second direction (e.g., the +X direction). In an embodiment, the first region SA1 may be a region that overlaps the first semiconductor chip 300 and the third semiconductor chip 700 in a vertical direction (e.g., the +Z direction). In an embodiment, the first semiconductor chip 300 may be mounted on the first region SA1 of the lower substrate 101. The third semiconductor chip 700 may be disposed to overlap the first semiconductor chip 300 in the vertical direction (e.g., the +Z direction) on the first region SA1 of the lower substrate 101. In an embodiment, the second region SA2 may be a region that overlaps the second semiconductor chip 500 and the redistribution structure 410 in the vertical direction (e.g., the +Z direction). In an embodiment, the first region SA1 may be adjacent to the first edge 1011, and the second region SA2 may be adjacent to the second edge 1012.

In an embodiment, the lower substrate 101 may include a first layer 101a, a second layer 101b and a third layer 101c, sequentially disposed in the vertical direction (e.g., the +Z direction).

In an embodiment, the first upper pad 110 may be disposed on (e.g., disposed directly thereon) an upper surface of the third layer 101c. The first upper pad 110 may be disposed on a region of the upper surface of the third layer 101c corresponding to the first region SA1. In an embodiment, the first lower pad 120 may be disposed on (e.g., disposed directly thereon) a lower surface of the first layer 101a. In an embodiment, the first lower pad 120 may be disposed on the lower surface of the first layer 101a corresponding to the first region SA1 and the second region SA2. In an embodiment, the first interconnection circuit layer 115 (e.g., a lower interconnection layer) may be embedded in the first to third layers 101a, 101b and 101c. In an embodiment, the first interconnection circuit layer 115 may include vias disposed in the first to third layers 101a, 101b and 101c to connect multiple redistribution layers spaced apart in the vertical direction (e.g., the +Z direction) thereto.

In an embodiment, the first upper pad 110, the first lower pad 120 and the first interconnection circuit layer 115 may form an electrical path connecting the upper and lower surfaces of the lower substrate 101 to each other. In an embodiment, the first upper pad 110, the first lower pad 120 and the first interconnection circuit layer 115 may include a metal material. In an embodiment, the metal material may include at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or an alloy containing two more more metals thereof.

In an embodiment, the lower connection bump 140 may be disposed on (e.g., disposed directly thereon) the lower surface of the lower substrate 101 and may be electrically connected to the first lower pad 120. In an embodiment, the lower connection bump 140 may comprise tin (Sn), indium (In), bismuth (Bi), antimony (Sb), copper (Cu), silver (Ag), zinc (Zn), lead (Pb) and/or an alloy thereof.

In an embodiment, the lower base 100 may further include a passive element 165. The passive element 165 (e.g., a capacitor) may be embedded in the lower substrate 101. In an embodiment, the passive element 165 may be embedded in the second layer 101b. However, embodiments of the present inventive concept are not necessarily limited thereto. In an embodiment, the passive element 165 may be electrically connected to the connection structures 170a and 170b (or the first semiconductor chip 300) through a connection terminal 160p and a connection pad 160c disposed on the lower surface of the second layer 101b. In an embodiment, as the passive element 165 is embedded in the lower substrate 101, a connection path with the connection structures 170a and 170b (or the first semiconductor chip 300) may be minimized. In an embodiment, the passive element 165 may overlap the second region SA2 of the lower substrate 101 in the vertical direction (e.g., the +Z direction). For example, the passive element 165 may overlap the second semiconductor chip 500 (e.g., in the +Z direction).

In an embodiment, a first connection pattern may be disposed on the first region SA1 of the lower substrate 101. The first connection pattern may be disposed on the first upper pad 110. In an embodiment, the first connection pattern may include a first connection pad 130 and a first connection bump 135 (e.g., consecutively stacked in the +Z direction). The first connection bump 135 may be disposed between the first upper pad 110 and the first connection pad 130 (e.g., in the +Z direction).

In an embodiment, the first semiconductor chip 300 may be disposed on the first region SA1 of the lower substrate 101. The first semiconductor chip 300 may be disposed on the first connection pattern, such as the first connection pad 130 and the first connection bump 135. The first semiconductor chip 300 may be mounted on the lower substrate 101 through the first connection pattern. The first semiconductor chip 300 may be electrically connected to the first interconnection circuit layer 115 through the first connection pattern and the first upper pad 110.

In an embodiment, the first semiconductor chip 300 may include a lower surface on which the first connection pad 130 is disposed, an upper surface opposite the lower surface (e.g., in the +Z direction) and side surfaces S1 to S4 connecting the lower surface and the upper surface. The first semiconductor chip 300 may have a first side surface S1 extending in the first direction (e.g., the +Y direction), a second side surface S2 opposite to the first side surface S1 (e.g., in the +X direction) and extending in the first direction (e.g., the +Y direction), a third side surface S3 extending in the second direction (+X direction) and a fourth side surface S4 opposite to the third side surface S3 (e.g., in the −Y direction) and extending in the second direction (e.g., the +X direction).

In an embodiment, the first semiconductor chip 300 may include a communication processor (CP). However, embodiments of the present inventive concept are not necessarily limited thereto, and the first semiconductor chip 300 may include a modem, a central processing unit (CPU) or a graphic processing unit (GPU) in some embodiments.

In an embodiment, the plurality of connection structures 170a and 170b may be disposed on the lower substrate 101. In an embodiment, the plurality of connection structures 170a and 170b may include a lower connection pad 171, a connection bump 173 and an upper connection pad 172 sequentially disposed in the vertical direction (e.g., the +Z direction). The lower connection pad 171 may be disposed on (e.g., disposed directly thereon) the upper surface of the lower substrate 101. In an embodiment, the lower connection pad 171 may be positioned at the same level (e.g., in the +Z direction) as the first upper pad 110. The connection bump 173 may be disposed between the lower connection pad 171 and the upper connection pad 172 (e.g., in the +Z direction). The upper connection pad 172 may be disposed on (e.g., disposed directly thereon) a lower surface of the upper base 200.

In an embodiment, the plurality of connection structures 170a and 170b may be disposed on the lower substrate 101 and surround the first semiconductor chip 300. In an embodiment, the plurality of connection structures 170a and 170b may include first connection structures 170a and second connection structures 170b sequentially disposed in the second direction (e.g., the +X direction). In an embodiment, the first connection structures 170a may be disposed on the first region SA1, and the second connection structures 170b may be disposed on the second region SA2, while the first connection structures 170a and the second connection structures 170b may be disposed on the same level (e.g., in the +Z direction) as each other.

In an embodiment, the first connection structures 170a may be disposed between an upper substrate 201 and the first region SA1 of the lower substrate 101 (e.g., in the +Z direction), and may support the upper substrate 201 and the third semiconductor chip 700 disposed on the upper substrate 201. In an embodiment, the second connection structures 170b may be disposed between the upper substrate 201 and the second region SA2 of the lower substrate 101 (e.g., in the +Z direction), and may support the upper substrate 201, and the redistribution structure 410 and the second semiconductor chip 500 disposed on the upper substrate 201. In an embodiment, the first connection structures 170a may overlap the third semiconductor chip 700 in the vertical direction (e.g., the +Z direction). In an embodiment, the second connection structures 170b may overlap the second semiconductor chip 500 in the vertical direction (e.g., the +Z direction).

In an embodiment, the first connection structures 170a may surround the first to fourth side surfaces S1 to S4 of the first semiconductor chip 300. In an embodiment, the connection structures 170a may include (1-1)-th to (1-4)-th connection structures 170a(P1) to 170a(P4). The (1-1)-th connection structures 170a(P1) may be adjacent to the first side surface S1 of the first semiconductor chip 300 and surround the first side surface S1. The (1-2)-th connection structures 170a(P2) may be adjacent to the second side surface S2 of the first semiconductor chip 300 and surround the second side surface S2. The (1-3)-th connection structures 170a(P3) may be adjacent to the third side surface S3 of the first semiconductor chip 300 and surround the third side surface S3. The (1-4)-th connection structures 170a(P4) may be adjacent to the fourth side surface S4 of the first semiconductor chip 300 and surround the fourth side surface S4. In an embodiment, the (1-1)-th connection structures 170a(P1) may be spaced apart from the (1-2)-th connection structures 170a(P2) in the second direction (e.g., the +X direction), and the (1-3)-th connection structures 170a(P3) may be spaced apart from the (1-4)-th connection structures 170a(P4) in the first direction (e.g., the +Y direction). In an embodiment, the (1-1)-th connection structures 170a(P1) may be adjacent to the first edge 1011 of the lower substrate 101. The (1-3)-th connection structures 170a(P3) may be adjacent to a portion of the third edge 1013 of the lower substrate 103. The (1-4)-th connection structures 170a(P4) may be adjacent to a portion of the fourth edge 1014 of the lower substrate 101.

In an embodiment, the second connection structures 170b may be disposed on the second region SA2 of the lower substrate 101, and may include (2-1)-th to (2-4)-th connection structures 170b(P2) to 170b(P5). In an embodiment, the (2-1)-th connection structures 170b(P2) may be disposed adjacent to the second edge 1012 of the lower substrate 101. The (2-2)-th connection structures 170b(P3) may be disposed adjacent to a portion of the third edge 1013 of the lower substrate 101. The (2-3)-th connection structures 170b(P4) may be disposed adjacent to a portion of the fourth edge 1014 of the lower substrate 101. The (2-4)-th connection structures 170b(P5) may be surrounded by the (2-1)-th to (2-3)-th connection structures 170b(P2) to 170b(P4) and the (1-2)-th connection structures 170a(P2) (e.g., in the +X and +Y directions).

In an embodiment, the second connection structures 170b may include peripheral connection structures 170b(P2), 170b(P3) and 170b(P4) adjacent to the edges of the lower substrate 101, and central connection structures 170b(P5) surrounded by the peripheral connection structures 170b(P2), 170b(P3) and 170b(P4) and the first semiconductor chip 300.

Hereinafter, the (2-1)-th connection structures 170b(P2) may be referred to as first peripheral connection structures 170b(P2), the (2-2)-th connection structures 170b(P3) may be referred to as second peripheral connection structures 170b(P3), and the (2-3)-th connection structures 170b(P4) may be referred to as third peripheral connection structures 170b(P4). The (2-4)-th connection structures 170b(P5) may be referred to as central connection structures 170b(P5).

In an embodiment, the (1-1)-th connection structures 170a(P1), the (1-2)-th connection structures 170a(P2) and the (2-1)-th connection structures 170b(P2) may extend in the first direction (+Y direction), and be spaced apart from each other in the second direction (+X direction). In an embodiment, the (2-2)-th connection structures 170b(P3) may be connection structures extending from the (1-3)-th connection structures 170a(P3) in the second direction (+X direction). The (2-3)-th connection structures 170b(P4) may be connection structures extending from the (1-4)-th connection structures 170a(P4) in the second direction (+X direction).

In an embodiment, support members 180 may be disposed on at least a portion of the plurality of connection structures 170a and 170b adjacent to the side surfaces of the first to third side surfaces S1 to S4 of the first semiconductor chip 300 and the edges 1011 to 1014 of the lower substrate 101. In an embodiment, the support members 180 may include solder balls. For example, in an embodiment the support members 180 may have a spherical or ball shape made of a metal having a low melting point, such as tin (Sn), indium (In), bismuth (Bi), antimony (Sb), copper (Cu), silver (Ag), zinc (Zn), lead (Pb) or an alloy containing the same (for example, Sn—Ag—Cu). For example, in an embodiment, the support members 180 may be a copper (CU) core ball. In an embodiment, the support members 180 may be disposed within the connection bumps 173 and may be sealed by the connection bumps 173.

In an embodiment, the support members 180 may include first support members 180a disposed on at least a portion of the first connection structures 170a and second support members 180b disposed on at least a portion of the second connection structures 170b. In an embodiment, the first support members 180a may be disposed in the first connection structures 170a surrounding at least two of the side surfaces S1 to S4 of the first semiconductor chip 300. In an embodiment, the second support members 180b may be disposed in the second connection structures 170b adjacent to at least one of the edges 1011 to 1014 of the lower substrate 101. In an embodiment, the support members 180 may not be disposed in the (2-4)-th connection structures 170b(P5) among the second connection structures 170b. However, embodiments of the present inventive concept are not necessarily limited thereto, and in another embodiment the support members 180 may be disposed in a portion of the (2-4)-th connection structures 170b(P5).

In an embodiment, the upper base 200 may be disposed on the plurality of connection structures 170a and 170b. In an embodiment, the upper base 200 may include the upper substrate 201, a second interconnection circuit layer 215 and second upper pads 220a and 220b.

In an embodiment, the upper substrate 201 is a support substrate on which the third semiconductor chip 700 and the redistribution structure 410 are mounted, and may be a substrate for a semiconductor package that includes a printed circuit board (PCB), a ceramic substrate, a glass substrate, a tape interconnection substrate or the like. In an embodiment, the upper substrate 201 may include the same or similar features as the lower substrate 101. In an embodiment, a height of the upper substrate 201 in the vertical direction (e.g., the +Z direction) may be lower than a height of the lower substrate 101 in the vertical direction (e.g., the +Z direction).

In an embodiment, the upper substrate 201 may be disposed on (e.g., disposed directly thereon in the +Z direction) the plurality of connection structures 170a and 170b.

In an embodiment, the second upper pads 220a and 220b may be disposed on an upper surface of the upper substrate 201. In an embodiment, the second upper pads 220a and 220b may include a (2-1)-th upper pad 220a disposed on the first region SA1 of the lower substrate 101 and a (2-2)-th upper pad 220b disposed on the second region SA2 of the lower substrate 101 and positioned at the same level (e.g., in the +Z direction) as the (2-1)-th upper pad 220a.

In an embodiment, the second interconnection circuit layer 215 (e.g., an upper interconnection layer) may be embedded in the upper substrate 201. The second interconnection circuit layer 215 may electrically connect the second upper pads 220a and 220b and the plurality of connection structures 170a and 170b to each other. In an embodiment, the second interconnection circuit layer 215 of the upper substrate 201 may be electrically connected to the first interconnection circuit layer 115 of the lower substrate 101 through the plurality of connection structures 170a and 170b.

In an embodiment, the second interconnection circuit layer 215 may further electrically connect the second upper pads 220a and 220b and the plurality of connection structures 170a and 170b in which the support members 180 are not disposed.

In an embodiment, the semiconductor package 1000 may further include an encapsulant 150 that fills a space between the lower substrate 101 and the upper substrate 201 and encapsulates side surfaces of the plurality of connection structures 170a and 170b and the first semiconductor chip 300. In an embodiment, the encapsulant 150 may fix and protect the plurality of connection structures 170a and 170b and the first semiconductor chip 300.

In an embodiment, the encapsulant 150 may include a thermosetting resin such as an epoxy resin, a thermoplastic resin such as polyimide, prepreg containing an inorganic filler or/and glass fiber, ABF, FR-4, BT, EMC, etc. The encapsulant 150 may have a molded underfill (MUF) structure. However, embodiments of the present inventive concept are not necessarily limited thereto. For example, in some embodiments, the encapsulant 150 may have a capillary underfill (CUF) structure.

In an embodiment, a third connection pattern may be disposed on the (2-1)-th upper pad 220a. In an embodiment, the third connection pattern may include a third connection bump 235 and a third connection pad 230 (e.g., consecutively stacked in the +Z direction). The third connection bump 235 may be disposed between the (2-1)-th upper pad 220a and the third connection pad 230 (e.g., in the +Z direction). The third connection pad 230 may be disposed on (e.g., disposed directly thereon) a lower surface of the third semiconductor chip 700.

In an embodiment, a second connection pattern may be disposed on the (2-2)-th upper pad 220b. In an embodiment, the second connection pattern may include a second connection bump 435 and a second connection pad 430 (e.g., consecutively stacked in the +Z direction). The second connection bump 435 may be disposed between the (2-2)-th upper pad 220b and the second connection pad 430 (e.g., in the +Z direction). The second connection pad 430 may be disposed on (e.g., disposed directly thereon) a lower surface of the redistribution structure 410.

In an embodiment, the second connection pattern and the third connection pattern may be disposed at the same level (e.g., in the +Z direction) on the upper substrate 201 as each other. In an embodiment, the redistribution structure 410 may be disposed on (e.g., disposed directly thereon) the second connection pattern 430 and 435. The redistribution structure 410 may overlap the second region SA2 of the lower substrate 101 in the vertical direction (e.g., the +Z direction). In an embodiment, the redistribution structure 410 may include a single layer or multilayer interconnection layer 411 and an insulating layer 412. In an embodiment in which the redistribution structure 410 has a multilayer interconnection structure, interconnections in different layers may be connected to each other through vertical contacts. In an embodiment, the redistribution structure 410 may be electrically connected to the second interconnection circuit layer 215 of the upper substrate 201 through the second connection pattern 430 and 435 and the (2-2)-th upper pad 220b.

In an embodiment, the semiconductor package 1000 may further include an underfill material layer 420 surrounding side surfaces of the redistribution structure 410 disposed on the upper substrate 201. In an embodiment, the underfill material layer 420 may be formed by a capillary underfill (CUF) process. However, embodiments of the present inventive concept are not necessarily limited thereto.

In an embodiment, the second semiconductor chip 500 may be disposed on the redistribution structure 410. In an embodiment, the second semiconductor chip 500 may include a substrate 501, a plurality of semiconductor dies 510 and 520, die connection patterns 555a and 555b and a sealant 530.

In an embodiment, the substrate 501 may be a substrate on which the plurality of semiconductor dies 510 and 520 are mounted. The substrate 501 may have similar features to the lower substrate 101 and/or the upper substrate 201 and a repeated description of similar or identical elements may be omitted for economy of description. The substrate 501 may be disposed on the redistribution structure 410. In an embodiment, the substrate 501 may be bonded onto the redistribution structure 410 through pads disposed on a lower portion of the substrate 501.

In an embodiment, the plurality of semiconductor dies 510 and 520 may be sequentially disposed on the substrate 501 in the vertical direction (e.g., the +Z direction). In an embodiment, the plurality of semiconductor dies 510 and 520 may include a first die 510 and a second die 520. The first die 510 and the second die 520 may be sequentially disposed on the redistribution structure 410 in the vertical direction (e.g., the +Z direction). Although the number of stacked semiconductor dies is shown as two in FIG. 2, embodiments of the present inventive concept are not necessarily limited thereto, and three or more semiconductor dies may be included in some embodiments.

In an embodiment, the first die 510 may include a first base substrate 510a, a first circuit layer 510b disposed on the first base substrate 510a and though-electrodes penetrating the first circuit layer 510b (e.g., in the +Z direction). In an embodiment, the first die 510 may be disposed on the substrate 501 through a first die connection pattern 555a disposed on a lower surface of the first base substrate 510a. The first die 510 may be electrically connected to the substrate 501 through the first die connection pattern 555a.

In an embodiment, the second die 520 may include a second base substrate 520a and a second circuit layer 520b disposed on the second base substrate 520a. The second die 520 may be disposed on the first die 510 through a second die connection pattern 555b disposed on a lower surface of the second base substrate 520a. The second die 520 may be electrically connected to the first die 510 through the second die connection pattern 555b.

In an embodiment, the first and second base substrates 510a and 520a may include a semiconductor element such as silicon (Si) or germanium (Ge), or may include a compound semiconductor such as silicon carbide (SiC), gallium arsenide (GaAs), indium arsenide (InAs) or indium phosphide (InP).

In an embodiment, the first and second circuit layers 510b and 520b may be disposed on (e.g., disposed directly thereon) active surfaces of the first and second base substrates 510a and 520a, respectively, and may include an interlayer insulating layer and an interconnection structure. In an embodiment, the interlayer insulating layer may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. In an embodiment, the interlayer insulating layer may be formed by means of a chemical vapor deposition (CVD) process, a flowable-CVD process or a spin coating process. In an embodiment, the interconnection structure may be embedded in the interlayer insulating layer. The interconnection structure may be formed in a multilayer structure including vias and interconnection patterns made of aluminum (Al), gold (Au), cobalt (Co), copper (Cu), nickel (Ni), lead (Pb), tantalum (Ta), tellurium (Te), titanium (Ti), tungsten (W), or combinations thereof.

The through-electrodes 515 of the first die 510 may penetrate the first circuit layer 510b (e.g., in the +Z direction) and electrically connect the first and second die connection patterns 555a and 555b to each other.

In an embodiment, the sealant 530 may surround the substrate 501 and the plurality of semiconductor dies 510 and 520 on the redistribution structure 410.

In an embodiment, the second semiconductor chip 500 may include a logic chip, a processor chip or a controller chip. In an embodiment, the second semiconductor chip 500 may include a system on chip (SoC), an application processor (AP), a mobile AP, a chip set, or a set of chips. In an embodiment, the second semiconductor chip 500 may be a semiconductor chip that performs a different function from the first semiconductor chip 300.

In an embodiment, the third semiconductor chip 700 may be disposed on the third connection pattern 230 and 235 disposed on the upper substrate 201. The third semiconductor chip 700 may be electrically connected to the second interconnection circuit layer 215 of the upper substrate 201 through the third connection pattern 230 and 235 and the (2-1)-th upper pad 220a. In an embodiment, the third semiconductor chip 700 may be spaced apart from the second semiconductor chip 500 in the second direction (e.g., the +X direction).

In an embodiment, the third semiconductor chip 700 may overlap the first semiconductor chip 300 in the vertical direction (e.g., the +Z direction). In an embodiment, the third semiconductor chip 700 may cover the first region SA1 of the lower substrate 101.

In an embodiment, the third semiconductor chip 700 may include a memory chip. For example, the third semiconductor chip 700 may include a volatile memory chip such as a random access memory (RAM), a dynamic RAM (DRAM) or a static RAM (SRAM). However, the third semiconductor chip 700 is not necessarily limited to a volatile memory chip, and may include a storage memory chip such as a non-volatile memory chip.

The semiconductor package 1000 according to an embodiment of the present inventive concept may include the support members 180 disposed in at least a portion of the plurality of connection structures 170a and 170b, thereby reducing a warpage of the semiconductor package 1000. In addition, a bonding height between the lower substrate 101 and the upper substrate 201 may be secured by the support members 180, thereby ensuring structural reliability.

In an embodiment, the first direction (Y) and the second direction (X) may be perpendicular to each other. The first direction (Y) and the second direction (X) may be perpendicular to the vertical direction (Z). However, embodiments of the present inventive concept are not necessarily limited thereto and the first to third directions may cross each other at various different angles.

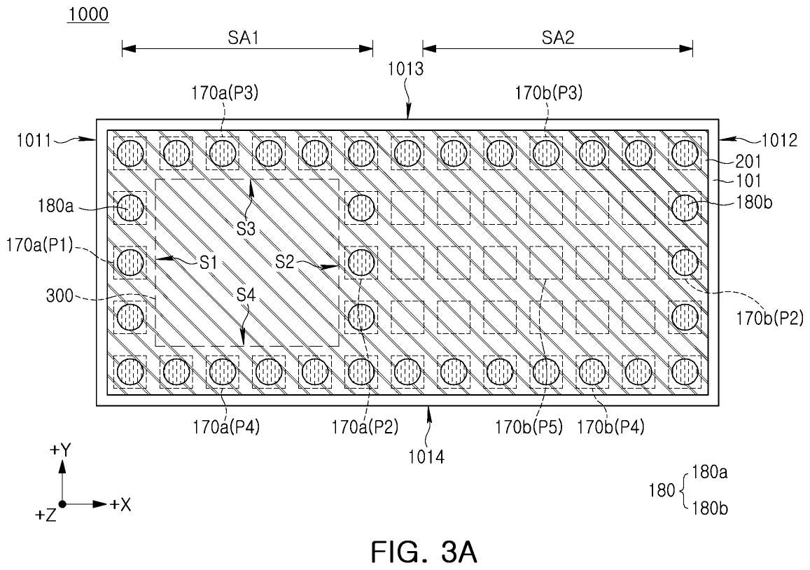

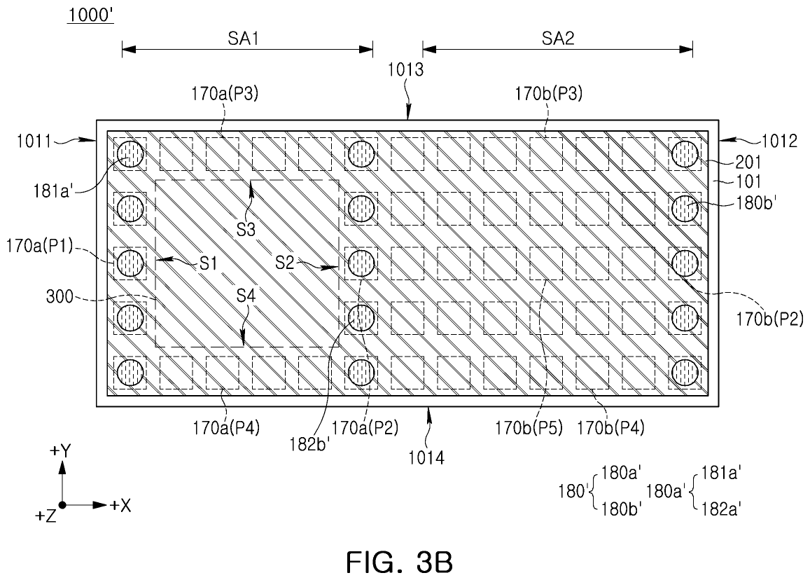

FIGS. 3A and 3B are plan views of an arrangement of the support members of the semiconductor package of FIG. 2 according to embodiments of the present inventive concept.

Referring to FIG. 3A, the support members 180 may be disposed in the connection structures 170a and 170b adjacent to the side surfaces S1 to S4 of the first semiconductor chip 300 and the edges 1011 to 1014 of the lower substrate 101. In an embodiment, the support members 180 may include the first support members 180a disposed in the first connection structures 170a and the second support members 180b disposed in the peripheral connection structures 170b(P2), 170b(P3) and 170b(P4) among the second connection structures 170b.

In an embodiment, the first support members 180a may be disposed in each of the (1-1)-th to (1-4)-th connection structures 170a(P1) to 170a(P4) adjacent to the first semiconductor chip 300. In an embodiment, the first support members 180a may surround the first semiconductor chip 300 (e.g., completely surround the first semiconductor chip 300 in the +X and +Y directions).

In an embodiment, the second support members 180b may be disposed in each of the (2-1)-th to (2-3)-th connection structures 170b(P2) to 170b(P4) adjacent to the second edge 1012, the third edge 1013 and the fourth edge 1014 of the lower substrate 101.

In an embodiment, the support members 180 may be disposed in each of the (1-1)-th connection structures 170a(P1), the (1-3)-th connection structures 170a(P3), the (1-4)-th connection structures 170a(P4) and the (2-1)-th to (2-3)-th connection structures 170b(P2) to 170b(P3) adjacent to the edges of the lower substrate 101.

In an embodiment, the support members 180 may not be disposed in a portion of the plurality of connection structures 170a and 170b. In an embodiment, the support members 180 may not be disposed in the (2-4)-th connection structures 170b(P5) (e.g., the central connection structures) surrounded by the (1-2)-th connection structures 170a(P2) and the (2-1)-th to (2-3)-th connection structures 170b(P2) to 170b(P4). In an embodiment, the upper substrate 201 may be electrically connected to the lower substrate 101 through the (2-4)-th connection structures 170b(P5).

Except for support members 180′ shown in FIG. 3B, the remaining components may be the same as or correspond to the components shown in FIGS. 2 and 3A. Redundant descriptions of identical or corresponding components may be omitted for economy of description.

Referring to FIG. 3B, a semiconductor package 1000′ may include support members 180′. In an embodiment, the support members 180′ may include first support members 180a′ and second support members 180b′.

In an embodiment, the first support members 180a′ may include (1-1)-th support members 181a′ disposed in the (1-1)-th connection structures 170a(P1) and (1-2)-th support members 182a′ disposed in the (1-2)-th connection structures 170a(P2). In an embodiment, the first support members 180a′ may not be disposed in the (1-3)-th connection structures 170a(P3) and the (1-4)-th connection structures 170a(P4). In an embodiment, the upper substrate 201 may be electrically connected to the lower substrate 101 through the (1-3)-th connection structures 170a(P3) and the (1-4)-th connection structures 170a(P4).

In an embodiment, the second support members 180b′ may be disposed in the (2-1)-th connection structures 170b(P2). The second support members 180b′ may not be disposed in the (2-2)-th connection structure 170b(P3), the (2-3)-th connection structures 170b(P4) and the (2-4)-th connection structures 170b(P5). In an embodiment, the upper substrate 201 may be electrically connected to the lower substrate 101 through the (2-2)-th to (2-4)-th connection structures 170b(P3) to 170b(P5).

In an embodiment, the (1-1)-th support members 181a′, the (1-2)-th support members 182a′ and the second support members 180b′ may sequentially disposed to be spaced apart from each other in the second direction (+X direction).

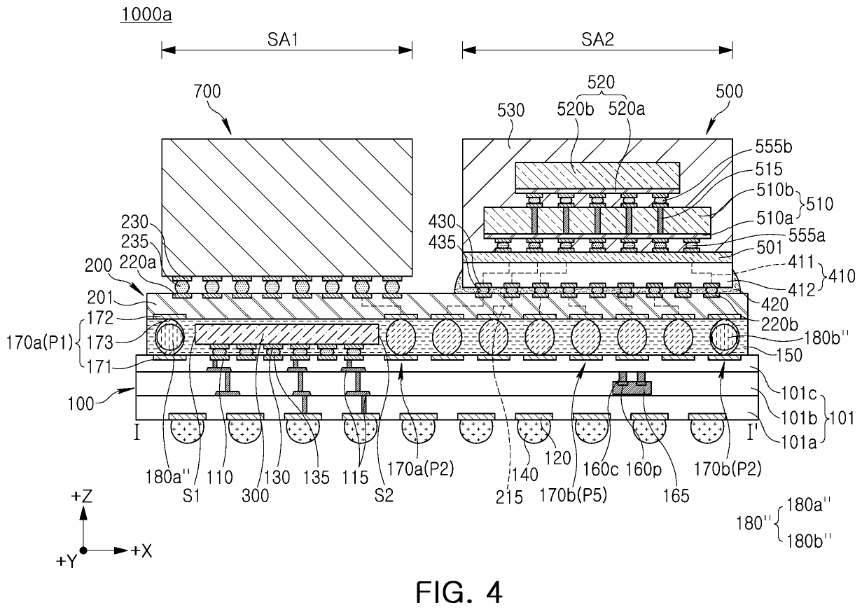

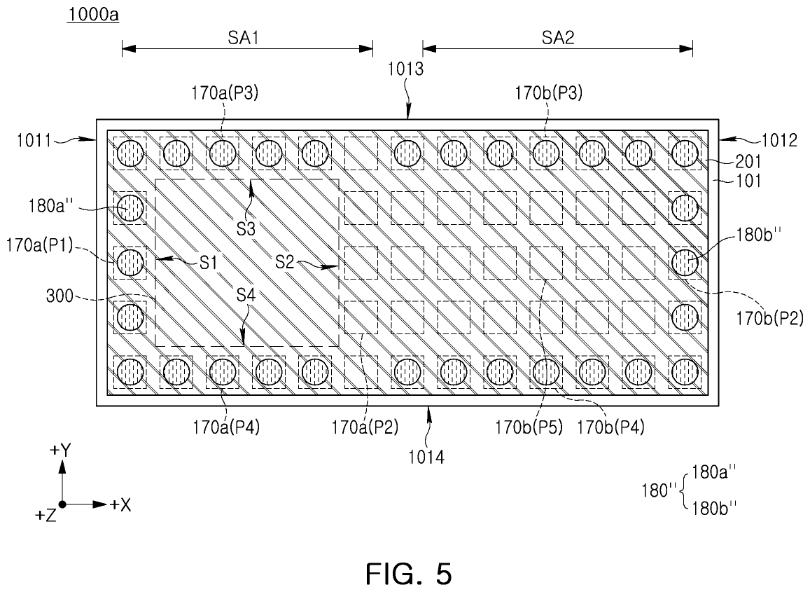

FIG. 4 is a cross-sectional view taken along line I-I′ in FIG. 1 according to an embodiment of the present inventive concept. FIG. 5 is a plan view of the arrangement of the support members of the semiconductor package of FIG. 4 according to an embodiment of the present inventive concept.

Except for support members 180″ shown in FIGS. 4 and 5, the remaining components may be the same as or correspond to the components shown in FIG. 2. Redundant descriptions of identical or corresponding components may be omitted for economy of description.

Referring to FIGS. 4 and 5, a semiconductor package 1000a may include support members 180″. In an embodiment, the support members 180″ may include first support members 180a″ disposed on a portion of the first connection structures 170a and second support members 180b″ disposed on a portion of the second connection structures 170b.

Referring to FIG. 5, the support members 180″ may not be disposed in the (1-2)-th connection structures 170a(P2) and the central connection structures 170b(P5) (e.g., the (2-4)-th connection structures).

Referring to FIG. 5, the first support members 180a″ may be disposed in the first connection structures 170a surrounding the first side surface S1, the third side surface S3 and the fourth side surface S4 of the first semiconductor chip 300. For example, in an embodiment, the first support members 180a″ may be disposed in the (1-1)-th connection structures 170a(P1), the (1-3)-th connection structures 170a(P3) and the (1-4)-th connection structures 170a(P4). In an embodiment, the second support members 180b″ may be disposed in the second connection structures 170b adjacent to the second edge 1012, the third edge 1013 and the fourth edge 1014 of the lower substrate 101. In an embodiment, the second support members 180b″ may be disposed in the peripheral connection structures 170b(P2) to 170b(P4) among the second connection structures 170b. The second support members 180b″ may be disposed in the (2-1)-th connection structures 170b(P2), the (2-2)-th connection structures 170b(P3) and the (2-3)-th connection structures 170b(P4).

In an embodiment, the first support members 180a″ and the second support members 180b″ may be spaced apart from each other with the (1-2)-th connection structures 170a(P2) interposed therebetween (e.g., in the +X direction).

In an embodiment, the upper substrate 201 may be electrically connected to the lower substrate 101 through the (1-2)-th connection structures 170a(P2) and the (2-4)-th connection structures 170b(P5).

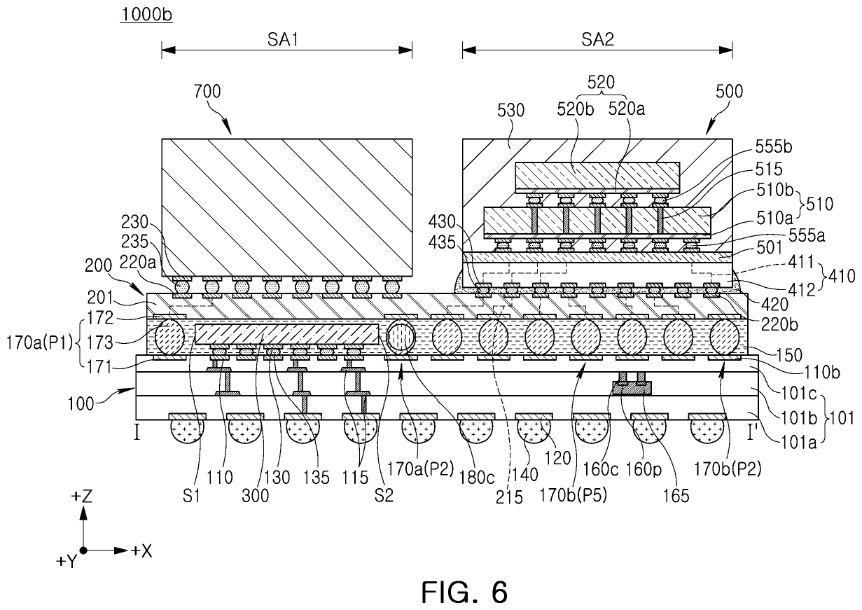

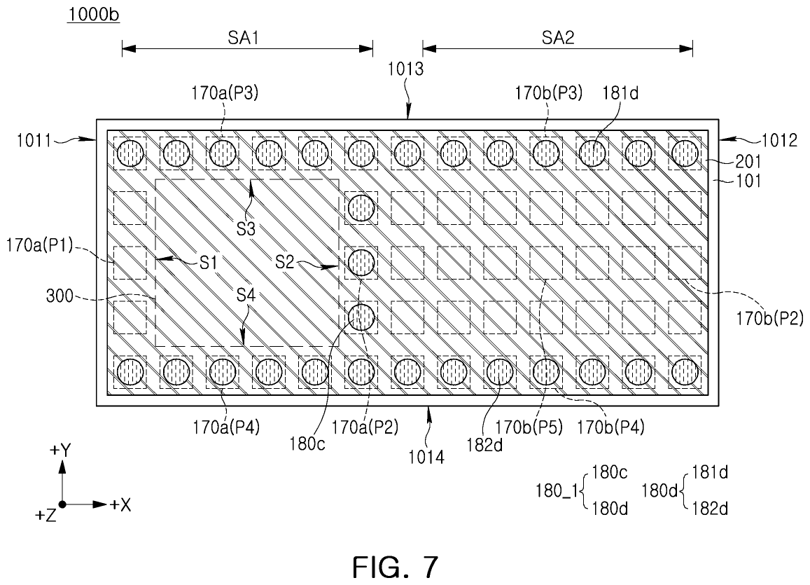

FIG. 6 is a cross-sectional view taken along line I-I′ in FIG. 1 according to an embodiment of the present inventive concept. FIG. 7 is a plan view of the arrangement of the support members of the semiconductor package of FIG. 6 according to an embodiment of the present inventive concept;

Except for support members 180_1 shown in FIGS. 6 and 7, the remaining components may be the same as or correspond to the components shown in FIG. 2. Redundant descriptions of identical or corresponding components may be omitted for economy of description.

Referring to FIGS. 6 and 7, a semiconductor package 1000b may include support members 180_1. In an embodiment, the support members 180_1 may include first support members 180c disposed on a portion of the first connection structures 170a and second support members 180d disposed on a portion of the second connection structures 170b. The support members 180_1 may not be disposed in the (1-1)-th connection structures 170a(P1), the (2-1)-th connection structures 170b(P2) and the central connection structures 170b(P5) (e.g., the (2-4)-th connection structures).

In an embodiment, the first support members 180c may be disposed in the first connection structures 170a surrounding the second side surface S2, the third side surface S3 and the fourth side surface S4 of the first semiconductor chip 300. In an embodiment, the first support members 180c may be disposed in the (1-2)-th connection structures 170a(P2), the (1-3)-th connection structures 170a(P3) and the (1-4)-th connection structures 170a(P4)). In an embodiment, the second support members 180d may be disposed in the second connection structures 170b adjacent to the third edge 1013 and the fourth edge 1014 of the lower substrate 101. The second support members 180d may be disposed in the (2-2)-th connection structures 170b(P3) and the (2-3)-th connection structures 170b(P4).

In an embodiment, the upper substrate 201 may be electrically connected to the lower substrate 101 through the (1-1)-th connection structures 170a(P1), the (2-1)-th connection structures 170b(P2) and the central connection structure 170b(P5).

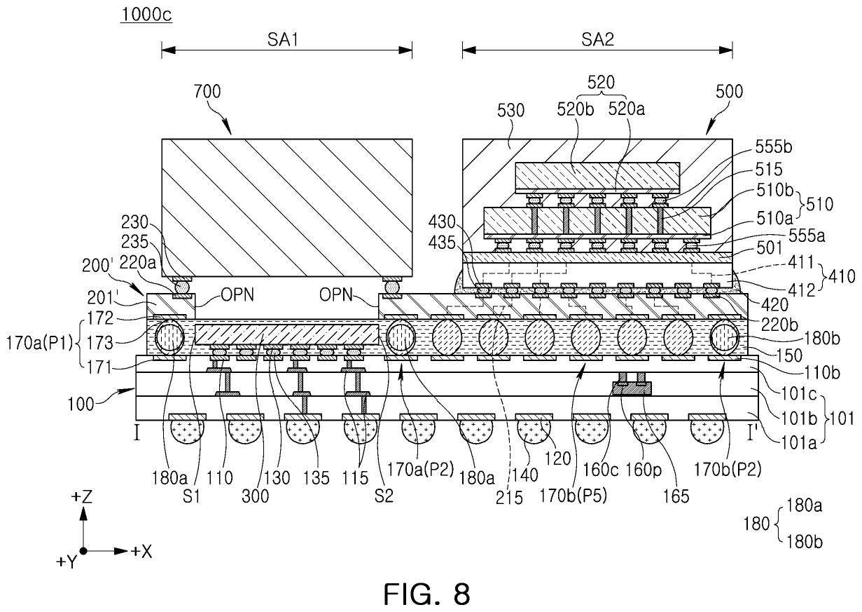

FIG. 8 is a cross-sectional view taken along line I-I′ in FIG. 1 according to an embodiment of the present inventive concept.

Except for the upper base 200′ shown in FIG. 8, the remaining components may be the same as or correspond to the components shown in FIG. 2. Redundant descriptions of identical or corresponding components may be omitted for economy of description.

Referring to FIG. 8, a semiconductor package 1000c may include an upper base 200′. In an embodiment, the upper base 200′ may include an upper substrate 201′ and the second interconnection circuit layer 215.

In an embodiment, the upper substrate 201′ may be disposed on the plurality of connection structures 170a and 170b. In an embodiment, the upper substrate 201′ may include a through-hole OPN exposing at least a portion of the first semiconductor chip 300. In an embodiment, the first semiconductor chip 300 may not overlap the upper substrate 201 in the vertical direction (e.g., the +Z direction). In an embodiment, at least a portion of the upper surface of the first semiconductor chip 300 may be exposed to the outside while being covered by the encapsulant 150.

In an embodiment, a width of the through-hole OPN of the upper substrate 201′ in the second direction (e.g., the +X direction) may correspond to a width of the first semiconductor chip 300 (e.g., in the +X direction).

In the semiconductor package 1000c according to an embodiment, heat generated from the first semiconductor chip 300 may be easily released through the through-hole OPN of the upper substrate 201 exposing at least a portion of the first semiconductor chip 300.

In an embodiment, the support members 180 may include the first support members 180a disposed in the first connection structures 170a surrounding the first semiconductor chip 300 and the second support members 180b disposed in the second connection structures 170a adjacent to the edges of the lower substrate 101.

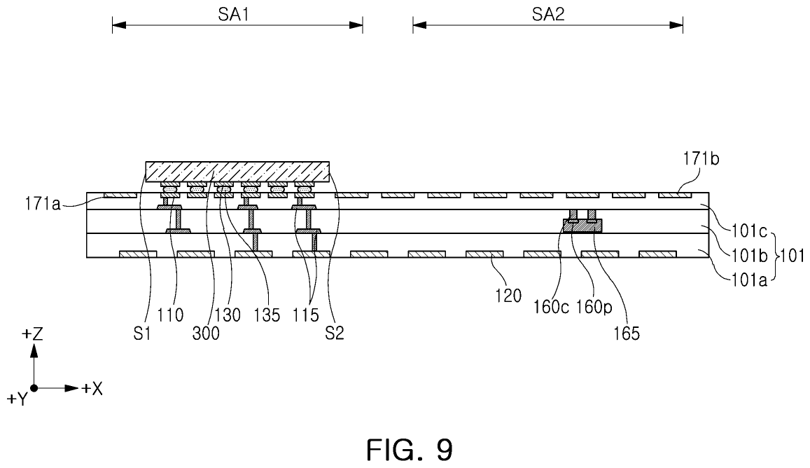

FIGS. 9 to 14 are diagrams of a method of manufacturing the semiconductor package of FIG. 2 according to embodiments of the present inventive concept.

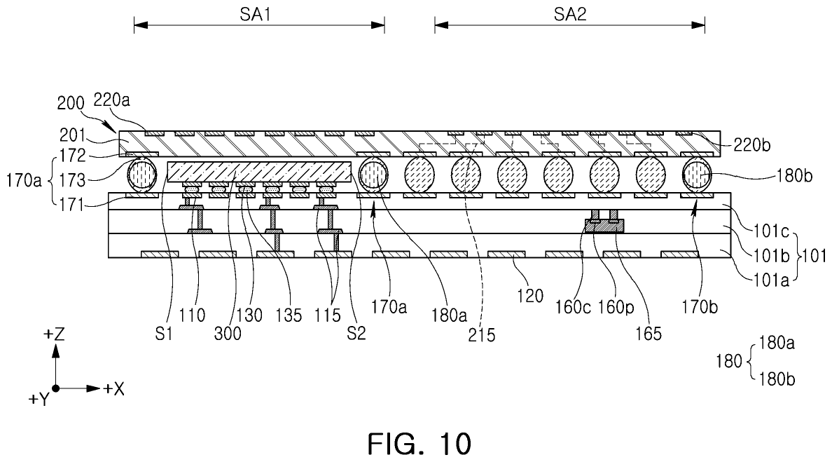

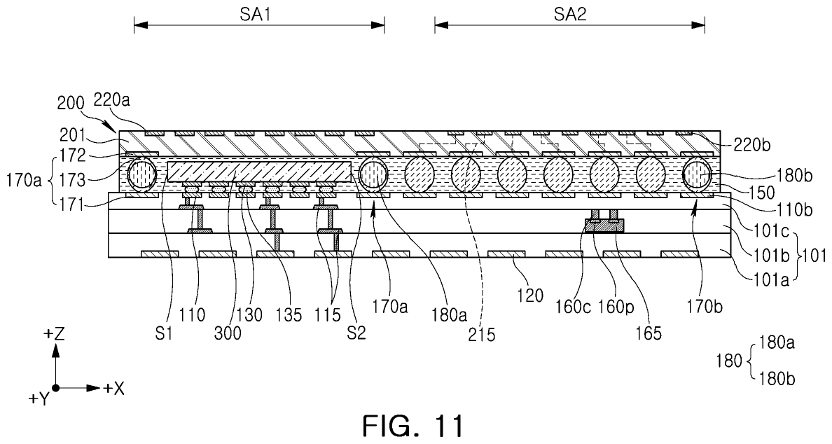

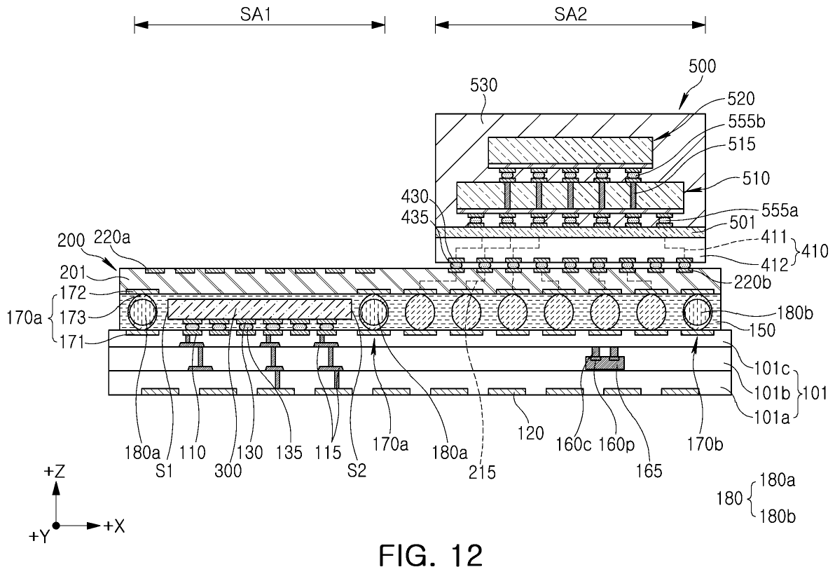

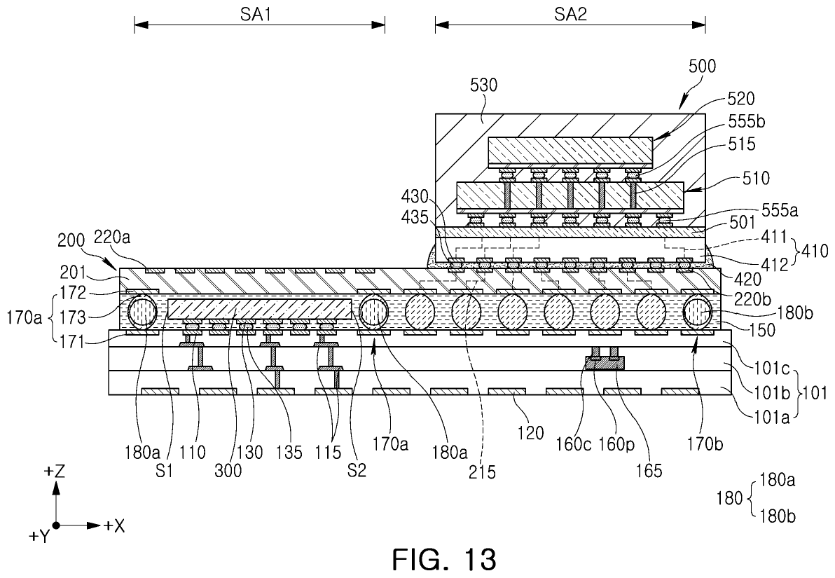

The method of manufacturing a semiconductor package according to embodiments of the present inventive concept may include the steps of forming a lower substrate 101 including a first region SA1 and a second region SA2 spaced apart from the first region SA1 in a second direction (e.g., the +X direction), forming a first semiconductor chip 300 on the first region SA1 of the lower substrate 101 (see FIG. 9), forming a plurality of connection structures 170a and 170b surrounding the semiconductor chip 300 on the lower substrate 101, forming an upper substrate 201 on the plurality of connection structures 170a and 170b and the first semiconductor chip 300 (see FIG. 10), forming an encapsulant 150 filling a space between the lower substrate 101 and the upper substrate 201 and encapsulating the plurality of connection structures 170a and 170b and the first semiconductor chip 300 (see FIG. 11), sequentially forming a redistribution structure 410 and a second semiconductor chip 500 on the upper substrate 201 overlapping the second region SA2 (see FIG. 12), forming an underfill material layer 420 covering side surfaces of the redistribution structure 410 on the upper substrate 201 (see FIG. 13), and forming a third semiconductor chip 700 on the upper substrate 201 overlapping the first region SA1.

Referring to FIG. 9, the method of manufacturing the semiconductor package 1000 may include the step of forming the lower substrate 101 including the first region SA1 and the second region SA2 spaced apart from the first region SA1 in the second direction (e.g., the +X direction). In an embodiment, the lower substrate 101 may be formed of a plurality of layers 101a, 101b and 101c. A first interconnection circuit layer 115 and a passive element 165 may be formed to be embedded within the plurality of layers 101a, 101b and 101c.

In an embodiment, a first upper pad 110 and lower connection pads 171a and 171b may be formed on (e.g., formed directly thereon) an upper surface of the lower substrate 101. The first upper pad 110 may be formed on the first region SA1. The lower connection pads 171a and 171b may be formed to surround the first upper pad 110 across the first region SA1 and the second region SA2 on the lower substrate 101. In an embodiment, the lower connection pads 171a and 171b may be lower connection pads that constitute a plurality of connection structures (e.g., the plurality of connection structures 170a and 170b in FIG. 2). In an embodiment, the lower connection pads 171a and 171b may include a first lower connection pad 171a and a second lower connection pad 171b. The first lower connection pad 171a may be formed on the first region SA1 while surrounding the first upper pad 110. The second lower connection pad 171b may be formed on the second region SA2.

In an embodiment, a first lower pad 120 may be formed on (e.g., formed directly thereon) a lower surface of the lower substrate 101. The first upper pad 110 and the lower connection pads 171a and 171b may be electrically connected to the first lower pad 120 through the first interconnection circuit layer 115.

In an embodiment, a connection terminal 160p and a connection pad 160c connected to the connection terminal 160p may be formed to be embedded in the second layer 101b. The passive element 165 may be formed below the connection pad 160c and the connection terminal 160p. The passive element 165 may be electrically connected to the first upper pad 110 (or lower connection pads 171a and 171b) through the connection terminal 160p and the connection pad 160c connected to the connection terminal 160p.

In an embodiment, a first connection pattern, such as a first connection pad 130 and a first connection bump 135, may be formed on the first upper pad 110. The first connection pattern may be a connection structure for mounting the first semiconductor chip 300 on the first region SA1 of the lower substrate 101.

In an embodiment, the first semiconductor chip 300 may be formed on the first connection pattern. The first semiconductor chip 300 may be electrically connected to the first interconnection circuit layer 115 (or passive element 160) of the lower substrate 101 through the first connection pattern, such as a first connection pad 130 and a first connection bump 135.

Referring to FIGS. 9 and 10, a plurality of connection structures 170a and 170b may be formed on (e.g., formed directly thereon) the lower substrate 101. In an embodiment, connection bumps 173 may be formed on (e.g., formed directly thereon) the first lower connection pad 171a and the second lower connection pad 171b. In an embodiment, an upper connection pad 172 may be formed on (e.g., formed directly thereon) the connection bump 173. The upper connection pad 172 may be formed on (e.g., formed directly thereon) a lower surface of the upper substrate 201.

In an embodiment, a first support member 180a may be formed in the first connection structures 170a surrounding the side surfaces of the first semiconductor chip 300 among the plurality of connection structures 170a and 170b. A second support member 180b may be formed in peripheral connection structures of the second connection structure 170b adjacent to the edges of the lower substrate 101 (e.g., the peripheral connection structures 170b(P2) to 170b(P4) of FIG. 1) among the plurality of connection structures 170a and 170b.

In an embodiment, an upper base 200 may be formed on (e.g., formed directly thereon) the plurality of connection structures 170a and 170b. For example, the upper substrate 201 may be formed on the plurality of connection structures 170a and 170b. An upper connection pad 172 may be formed on the lower surface of the upper substrate 201. Second upper pads 220a and 220b may be formed on an upper surface of the upper substrate 201. In an embodiment, a second interconnection circuit layer 215 may be embedded inside the upper substrate 201 to electrically connect the upper connection pad 172 and the second upper pads 220a and 220b to each other. In an embodiment, a (2-1)-th upper pad 220a of the second upper pads 220a and 220b may be formed on the upper substrate 201 to overlap the first region SA1. A (2-2)-th upper pad 220b may be formed on the upper substrate 201 to overlap the second region SA2.

Referring to FIG. 11, an encapsulant 150 filling a space (e.g., in the +Z direction) between the lower substrate 101 and the upper substrate 201 and encapsulating the side surfaces of the plurality of connection structures 170a and 170b and the first semiconductor chip 300 may be formed. In an embodiment, the encapsulant 150 may be formed by a transfer molding method in which an encapsulating material is injected in the second direction (e.g., the +X direction). However, embodiments of the present inventive concept are not necessarily limited thereto. For example, in an embodiment the encapsulant may be formed by a compression molding method in which an encapsulating material is injected in a vertical direction (e.g., the +Z direction).

Referring to FIG. 12, the redistribution structure 410 and the second semiconductor chip 500 may be sequentially formed on the (2-2)-th upper pad 220b (e.g., in the +Z direction).

In an embodiment, a second connection pattern, such as a second connection bump 435 and a second connection pad 430, may be formed on the (2-2)-th upper pad 220b. The second connection bump 435 may be formed on (e.g., formed directly thereon) the (2-2)-th upper pad 220b. A second connection pad 430 may be formed on (e.g., formed directly thereon) the second connection bump 435. The second connection pad 430 may be formed on (e.g., formed directly thereon) a lower surface of the redistribution structure 410. In an embodiment, an insulating layer 412 may be formed on the second connection pattern. In an embodiment, a single layer or multilayer interconnection layers 411 may be embedded in the insulating layer 412.

In an embodiment, the second semiconductor chip 500 may be formed on the redistribution structure 410. The second semiconductor chip 500 may be disposed to overlap the second region SA2 of the lower substrate 101 in the vertical direction (e.g., the +Z direction). In an embodiment, the second semiconductor chip 500 may include a substrate 501, a plurality of semiconductor dies 510 and 520, die connection patterns 555a and 555b and a sealant 530. The substrate 501, the first die 510 and the second die 520 may be sequentially formed on the redistribution structure 410 in the vertical direction (e.g., the +Z direction). A first die connection pattern 555a is formed between the substrate 501 and the first die 510 (e.g., in the +Z direction) so that the substrate 501 and the first die 510 may be electrically connected to each other. A second die connection pattern 555b may be formed between the first die 510 and the second die 520 (e.g., in the +Z direction), and through-electrodes 515 penetrating the first die 510 may be formed. The first die 510 may be electrically connected to the second die 520 through the second die connection pattern 555a and the through electrodes 515.

Referring to FIG. 13, the underfill material layer 420 may be formed surrounding side surfaces of the redistribution structure 410.

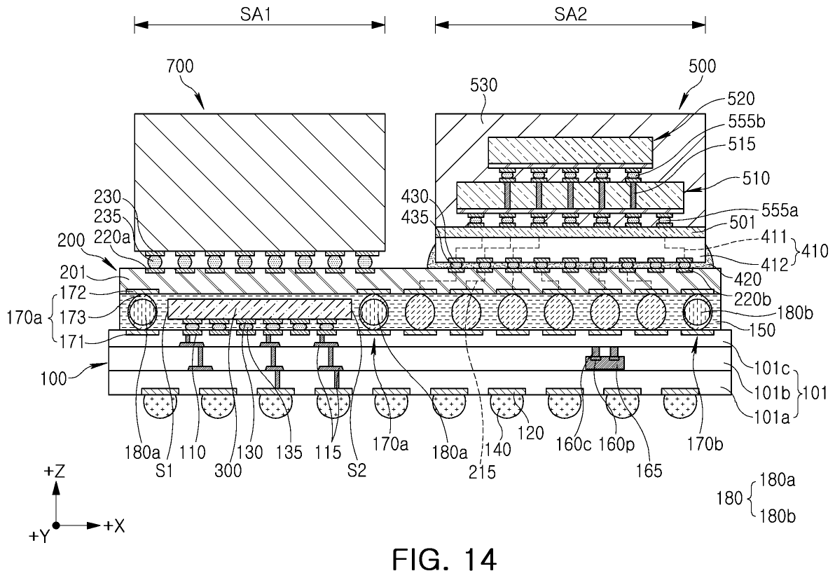

Referring to FIG. 14, the third semiconductor chip 700 may be formed on (e.g., formed directly thereon) the (2-1)-th upper pad 220a.

In an embodiment, a third connection pattern, such as a third connection pad 230 and a third connection bump 235, may be formed on the (2-1)-th upper pad 220a. The third connection bump 235 may be formed on (e.g., formed directly thereon) the (2-1)-th upper pad 220a. The third connection pad 230 may be formed on (e.g., formed directly thereon) the third connection bump 235. The third connection pad 230 may be formed on (e.g., formed directly thereon) a lower surface of the third semiconductor chip 700.

In an embodiment, the third semiconductor chip 700 may be formed on the third connection pattern. The third semiconductor chip 700 may be formed on the upper substrate 201 to overlap the first region SA1 of the lower substrate 101 in the vertical direction (e.g., the +Z direction). The third semiconductor chip 700 may overlap the first semiconductor chip 300 in the vertical direction (e.g., the +Z direction).

The method of manufacturing a semiconductor package according to an embodiment may further include forming a lower connection bump 140 on the lower surface of the lower substrate 101.

The method of manufacturing a semiconductor package according to an embodiment of the present inventive concept may form the support members 180 in the connection structures surrounding the side surfaces of the first semiconductor chip 300 and adjacent to the edges of the lower substrate 101 among the plurality of connection structures 170a and 170b formed between the lower substrate 101 and the upper substrate 201. Accordingly, it is possible to provide a semiconductor package having increased reliability by reducing warpage of the semiconductor package and securing the bonding height between the lower substrate 101 and the upper substrate 201.

According to an embodiment of the present inventive concept, it is possible to provide a semiconductor package having increased integration by having a structure in which an application processor (AP) and a communication processor (CP) are spaced apart from each other as single system on chips (SOCs), respectively, and the communication processor is disposed below a memory chip.

According to an embodiment of the present inventive concept, it is possible to provide a semiconductor package having increased structural reliability by preventing warpage of the semiconductor package by disposing support members in connection structure adjacent to side surfaces of a semiconductor chip and edges of a lower substrate among the connection structures disposed between an upper substrate and the lower substrate, and securing a bonding height between the lower substrate and the upper substrate.

However, the effects of embodiments of the present inventive concept are not limited to the effects described above, and may be expanded in various ways without departing from the spirit and scope of the present inventive concept.

While example embodiments have been shown and described above, it will be apparent to those skilled in the art that modifications and variations could be made without departing from the scope of the present inventive concept.

What is claimed is:

1. A semiconductor package, comprising:
a lower substrate comprising a lower interconnection layer;
a first semiconductor chip on the lower substrate, the first semiconductor chip is electrically connected to the lower interconnection layer;
connection structures on the lower substrate, the connection structures surrounding the first semiconductor chip;
support members disposed on at least a portion of connection structures adjacent to side surfaces of the first semiconductor chip and edges of the lower substrate of the connection structures;
an upper substrate disposed on the first semiconductor chip and the connection structures, the upper substrate comprising an upper interconnection layer;
a second semiconductor chip on the upper substrate, the second semiconductor chip is electrically connected to the upper interconnection layer; and
a third semiconductor chip disposed on the upper substrate, the third semiconductor chip is electrically connected to the upper interconnection layer, spaced apart from the second semiconductor chip in a horizontal direction, and overlaps the first semiconductor chip in a vertical direction.

2. The semiconductor package of claim 1, wherein each of the connection structures comprises:
a lower connection pad disposed on an upper surface of the lower substrate;
an upper connection pad disposed on a lower surface of the upper substrate; and
a connection bump disposed between the lower connection pad and the upper connection pad,
wherein each of the support members is disposed in the connection bump.

3. The semiconductor package of claim 1, wherein the connection structures comprise:
first connection structures surrounding the side surfaces of the first semiconductor chip and overlapping the third semiconductor chip in the vertical direction; and
second connection structures overlapping the second semiconductor chip in the vertical direction,
wherein the second connection structures comprise peripheral connection structures adjacent to the edges of the lower substrate, and central connection structures surrounded by the peripheral structures and the first semiconductor chip.

4. The semiconductor package of claim 3, wherein the support members are disposed solely in the first connection structures and the peripheral connection structures.

5. The semiconductor package of claim 3, wherein the support members comprise:
first support structures disposed on at least a portion of the first connection structures; and
second support structures disposed on at least a portion of the peripheral connection structures.

6. The semiconductor package of claim 5, wherein the first connection structures comprise:
(1-1)-th connection structures adjacent to a first side surface of the first semiconductor chip extending along a first direction;
(1-2)-th connection structures adjacent to a second side surface of the first semiconductor chip extending along the first direction and opposite to the first side surface in a second direction perpendicular to the first direction;
(1-3)-th connection structures adjacent to a third side surface of the first semiconductor chip extending along the second direction; and
(1-4)-th connection structures adjacent to a fourth side surface of the first semiconductor chip extending along the second direction and opposite the third side surface in the first direction,
wherein the first support members are disposed in at least two connection structures of the (1-1)-th to the (1-4)-th connection structures.

7. The semiconductor package of claim 6, wherein:
the lower substrate comprises a first edge extending along the first direction, a second edge parallel to the first edge in the first direction, a third edge extending along the second direction, a fourth edge parallel to the second edge in the second direction; and
the first semiconductor chip is adjacent to the first edge, and the second semiconductor chip is adjacent to the second edge.

8. The semiconductor package of claim 7, wherein the peripheral connection structures comprise:
first peripheral connection structures adjacent to the second edge;
second peripheral connection structures adjacent to the third edge; and
third peripheral connection structures adjacent to the fourth edge, and
the central connection structures are surrounded by the first to third peripheral connection structures and the (1-2)-th connection structures.

9. The semiconductor package of claim 8, wherein:
the first support members are disposed in the (1-1)-th connection structures and the (1-2)-th connection structures; and
the second support members are disposed in the first peripheral connection structures.

10. The semiconductor package of claim 8, wherein:
the first support members are disposed in the (1-1)-th connection structures, the (1-3)-th connection structures and the (1-4)-th connection structures; and
the second support members are disposed in the peripheral connection structures.

11. The semiconductor package of claim 8, wherein:
the first support members are disposed in the (1-2)-th connection structures, the (1-3)-th connection structures and the (1-4)-th connection structures; and
the second support members are disposed in the second peripheral connection structures and the third peripheral connection structures.

12. The semiconductor package of claim 1, wherein the upper substrate comprises a through-hole exposing at least a portion of the first semiconductor chip.

13. The semiconductor package of claim 1, wherein:
the first semiconductor chip comprises a communication processor (CP), the second semiconductor chip comprises an application processor (AP); and
the third semiconductor chip comprises a memory chip.

14. The semiconductor package of claim 1, wherein the support members comprise a copper (CU) core ball.

15. The semiconductor package of claim 1, further comprising:
a capacitor embedded in the lower substrate and overlapping the second semiconductor chip.

16. A semiconductor package, comprising:
a lower substrate comprising a first region and a second region spaced apart from the first region in a first direction;
a first semiconductor chip on the first region, the first semiconductor chip is electrically connected to the lower interconnection layer;
connection structures on the first region and the second region, the connection structures surrounding the first semiconductor chip;
support members disposed on at least a portion of connection structures adjacent to side surfaces of the first semiconductor chip and edges of the lower substrate of the connection structures;
an upper substrate disposed on the first semiconductor chip and the connection structures and overlapping therewith in a vertical direction, the upper substrate comprising an upper interconnection layer;
a second semiconductor chip on the upper substrate, the second semiconductor chip is electrically connected to the upper interconnection layer and overlaps the second region in the vertical direction; and
a third semiconductor chip on the upper substrate, the third semiconductor chip is spaced apart from the second semiconductor chip in a horizontal direction and overlaps the first semiconductor chip in the vertical direction.

17. The semiconductor package of claim 16, wherein the connection structures comprise:
first connection structures surrounding the side surfaces of the first semiconductor chip and overlapping the third semiconductor chip in the vertical direction; and
second connection structures overlapping the second semiconductor chip in the vertical direction,
wherein the second connection structures comprise peripheral connection structures adjacent to the edges of the lower substrate, and central connection structures surrounded by the peripheral structures.

18. A semiconductor package, comprising:
a lower substrate comprising a first region and a second region spaced apart from the first region in a first direction;
a capacitor embedded in the lower substrate;
a first semiconductor chip on the first region, the first semiconductor chip is electrically connected to the lower interconnection layer;
first connection structures on the first region, the first connection structures are adjacent to side surfaces of the first semiconductor chip;
second connection structures on the second region, the second connection structures are disposed at a same level as the first connection structures;
support members disposed on at least a portion of the first connection structures and a portion of the second connection structures;
an upper substrate disposed on the first semiconductor chip, the first connection structures and the second connection structures and overlapping the lower substrate in a vertical direction, the upper substrate comprising an upper interconnection layer;
a second semiconductor chip on the upper substrate, the second semiconductor chip is electrically connected to the upper interconnection layer and overlaps the second region in the vertical direction; and
a third semiconductor chip on the upper substrate, the third semiconductor chips is spaced apart from the second semiconductor chip in a horizontal direction and overlaps the first semiconductor chip in the vertical direction.

19. The semiconductor package of claim 18, wherein the support members comprise:
first support structures disposed on at least a portion of the first connection structures; and
second support structures disposed on at least a portion of the second connection structures, and
the first support members surround the first semiconductor chip.

20. The semiconductor package of claim 18, wherein the first semiconductor chip comprises a communication processor (CP), the second semiconductor chip comprises an application processor (AP), and the third semiconductor chip comprises a memory chip.
